(19) United States
(12) Patent Application Publication
(10) Pub. No.: US 2025/0089241 A1
(43) Pub. Date: Mar. 13, 2025

(54) MEMORY DEVICE AND MANUFACTURING METHOD THEREOF

(71) Applicant: NANYA TECHNOLOGY CORPORATION, New Taipei City (TW)

(72) Inventor: Jhen-Yu TSAI, Kaohsiung City (TW)

(21) Appl. No.: 18/464,287

(22) Filed: Sep. 11, 2023

(51) Int. Cl. H10B 12/00

(52) U.S. Cl. CPC H10B 12/485; H10B 12/036; H10B 12/05; H10B 12/33; H10B 12/482

(57) ABSTRACT

A memory device includes a substrate, a capacitor, a transistor, a word line, a bit line contact and a body contact. The capacitor is over the substrate. The transistor is over the capacitor, and the transistor includes a channel region, a gate over the channel region, and a source and a drain on opposite sides of the channel region, in which the drain is over the capacitor. The word line is over and electrically connected to the gate of the transistor. The bit line contact is over and electrically connected to the source of the transistor. The body contact is below the source of the transistor.

### BACKGROUND

### Field of Disclosure

The present disclosure relates to a memory device and a manufacturing method thereof.

### Description of Related Art

During the operation of a transistor, the carrier stored in the floating body cell (FBC) is mainly generated by the impact ionization operated like channel hot-electron injection near drain side. The impact ionization creates electron and hole pairs, where electrons are withdrawn by drain, while holes are swept toward the floating body as a transient storage for n-channel devices. The OFF-state leakage current was considerably high due to the parasitic bipolar junction transistor (BJT) operation in the accumulated holes of the body.

### SUMMARY

Some embodiments of the present disclosure provide a memory device, including a substrate, a capacitor, a transistor, a word line, a bit line contact and a body contact. The capacitor is over the substrate. The transistor is over the capacitor, and the transistor includes a channel region, a gate over the channel region, and a source and a drain on opposite sides of the channel region, in which the drain is over the capacitor. The word line is over and electrically connected to the gate of the transistor. The bit line contact is over and electrically connected to the source of the transistor. The body contact is below the source of the transistor.

In some embodiments, a bottom of the drain is lower than a bottom of the source.

In some embodiments, a bottom of the source is vertically spaced apart from the body contact.

In some embodiments, the bit line contact vertically overlaps the body contact.

In some embodiments the drain is in contact with the capacitor.

In some embodiments, the memory device further includes a bit line over and in contact with the bit line contact.

Some embodiments of the present disclosure provide a memory device, including a plurality of memory cells, a word line, a plurality of bit line contacts, and a body contact. Each of the memory cells includes a transistor, and a capacitor electrically connected to the transistor. The word line is electrically connected to the transistor of each of the memory cells. Each of the bit line contacts is electrically connected to the transistor of a respective one of the memory cells. The body contact vertically below the bit line contacts.

In some embodiments the capacitor is in contact with a bottom of a drain of the transistor.

In some embodiments the transistor is at a higher level than the capacitor.

In some embodiments the bit line contacts and the body contact are at opposite sides of a source of the transistor.

In some embodiments the body contact and the capacitor are at a lower level than the transistor.

Some embodiments of the present disclosure provide a manufacturing method of a memory device, including forming a capacitor in a first dielectric layer, forming a body contact in the first dielectric layer, in which the body contact is spaced apart from the capacitor, forming an semiconductive layer over the first dielectric layer and covering the capacitor and the body contact, forming a transistor over the semiconductive layer, and forming a bit line contact in contact with a source of the transistor.

In some embodiments, forming the body contact includes forming a second dielectric layer over the first dielectric layer and the capacitor, forming a hard mask layer having an opening over the second dielectric layer, etching the first dielectric layer and the second dielectric layer through the opening of the hard mask layer to form a recess in the first dielectric layer and the second dielectric layer, removing the hard mask layer, forming a body contact material layer overfilling the recess, and performing a planarization process to the body contact material layer until the first dielectric layer is exposed.

In some embodiments, forming the transistor includes forming a hard mask layer over the semiconductive layer, in which the hard mask layer has an opening overlapping the capacitor, performing a first implantation process to form a drain of the transistor in the semiconductive layer through the opening of the hard mask layer as mask, and removing the hard mask layer.

In some embodiments, forming the transistor further includes performing a second implantation process to form the source of the transistor in the semiconductive layer and overlapping the body contact.

In some embodiments, a doping intensity of the first implantation process is stronger than a doping intensity of the second implantation process.

In some embodiments, a source of the transistor vertically overlaps the body contact, while the source of the transistor is vertically spaced apart from the body contact.

In some embodiments, a drain of the transistor is in contact with the capacitor.

In some embodiments, a bottom of a drain of the transistor is lower than a bottom of a source of the transistor.

In some embodiments, the manufacturing method further includes forming a bit line in contact with the bit line contact.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a top view of a memory array in some embodiments of the present disclosure.

FIG. 2 illustrates a cross-section view taken along line A-A in FIG. 1.

FIGS. 3-13 illustrate cross-section views of manufacturing method of the memory device in some embodiments of the present disclosure.

### DETAILED DESCRIPTION

The memory device in some embodiments of the present disclosure includes a body contact used to reduce the OFF-state leakage current of the transistor. Specifically, the body contact is in contact with the body of the transistor to introduce the accumulated holes out of the body of the transistor. Therefore, the OFF-state leakage current of the transistor is reduced.

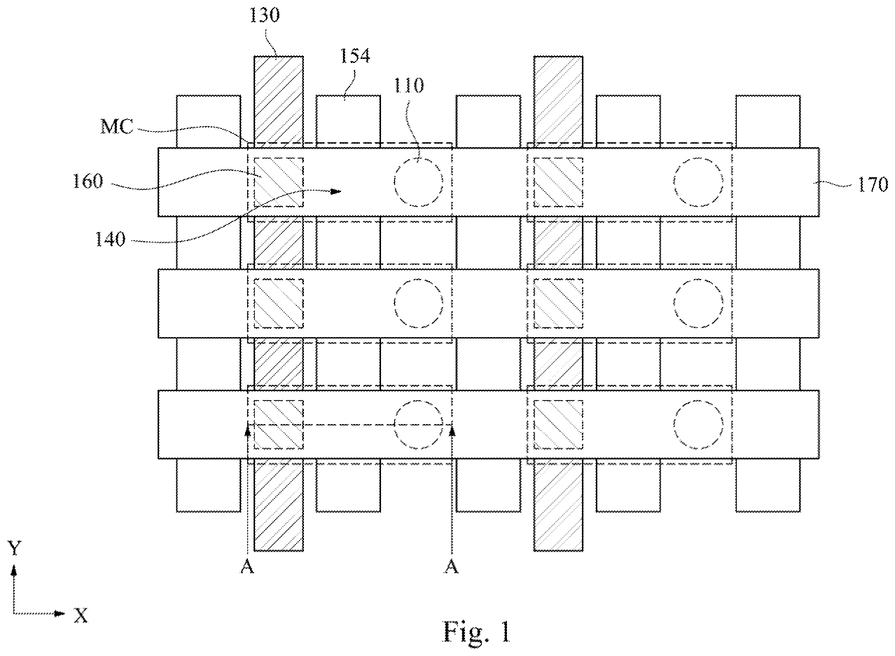

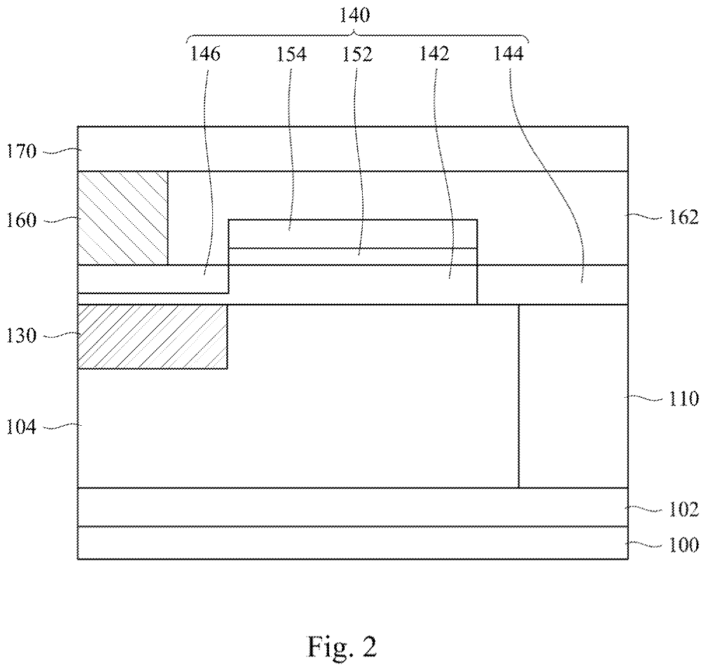

FIG. 1 illustrates a top view of a memory array in some embodiments of the present disclosure. FIG. 2 illustrates a cross-section view taken along line A-A in FIG. 1. Referring to FIG. 1, shown there is a memory array including a plurality of the memory cells. In some embodiments, the memory array of FIG. 1 is a DRAM array, which includes a plurality of DRAM cell. A typical DRAM cell incorporates capacitor 110 and a transistor (such as transistor 140 discussed in FIG. 2) in which the capacitor 110 temporarily store data based on the charged state of the capacitor 110. A bit line 170 is electrically connected with a drain region of the transistor, and a word line 154 is electrically connected with a gate region of the transistor. The bit line 170 has a lengthwise direction along a first direction X, and the word line 154 has a lengthwise direction along a second direction Y perpendicular to the first direction X. On the assumption that a pitch of each of word line 154 and bit line 170 is 2F, a horizontal size of DRAM cell can be 4F2, which means that the DRAM cell can have an area of approximately 4F2 or less, where F is a half pitch determined by a design rule.

A cross-sectional view of the memory device along line A-A of FIG. 1 is shown in FIG. 2, it is noted that some elements of FIG. 2 are not illustrated in FIG. 1 for simplicity. In FIG. 2, shown there is a semiconductor substrate 100. A conductive layer 102 is disposed on the semiconductor substrate 100. As mentioned above, each memory cell (such as DRAM cell) of the memory device includes a capacitor 110 and a transistor 140. The capacitor 110 is in a first dielectric layer 104 over the conductive layer 102. The transistor 140 of each memory cell may include a semiconductive layer 142, a drain 144, a source 146, and a gate dielectric layer 152. A word line 154 may also serve as a gate of the transistor 140, and thus the word line 154 may be interchangeably referred to as gate 154 of each transistor 140. From another perspective, the word line 154 is electrically connected with the gate of the transistor 140. It is noted that although FIGS. 1-2 illustrate that the word line 154 is a single gate structure, which means that the word line 154 is at one side of the channel (i.e. semiconductive layer 142), the word line 154 in the memory device may also be a double gate structure, a tri-gate structure or a surrounding gate structure.

Specifically, the capacitor 110 is over the semiconductor substrate 100. The transistor 140 is over the capacitor 110. The portion of the semiconductive layer 142 between the drain 144 and the source 146 is referred to as a channel region of the transistor 140. A gate (i.e. word line 154 in the present disclosure) is over the channel region. The source 146 and the drain 144 are on opposite sides of the channel region, in which the drain 144 is over the capacitor 110. The gate dielectric layer 152 is over the transistor 140, and the word line 154 is over the gate dielectric layer 152. The memory device further includes a bit line contact 160 and a body contact 130. The bit line contact 160 is over and in electrically connected with the source 146 of the transistor 140, and the body contact 130 is below the source 146 of the transistor 140. That is, the bit line contact 160 and the body contact 130 are at opposite sides of the transistor 140, and the body contact 130 and the capacitor 110 are at the same side of the transistor 140. For example, the body contact 130 and the capacitor 110 are at a lower level than the transistor 140, and the transistor 140 is at a higher level than the capacitor 110. A bottom of the source 146 is vertically spaced apart from the body contact 130, and the semiconductive layer 142 extends between the source 146 and the body contact 130. The memory device further includes a dielectric layer 162 and a bit line 170. The bit line 170 is over and in contact with the bit line contact 160. The dielectric layer 162 covers the transistor 140 and laterally surrounds the bit line contact 160.

Referring back to FIG. 1, the memory array in FIG. 1 may include a plurality of memory cells MC arranged in a matrix. For example, the memory cells MC are arranged in a 2×3 matrix as shown in FIG. 1, while the disclosure is not limited thereto. Each of the memory cells MC includes a transistor 140 and a capacitor 110 electrically connected to the transistor 140. The memory array further includes a plurality of word lines 154, a plurality of bit lines 170. Each of the word line 154 is electrically connected to the transistors 140 that are arranged along Y-direction. Each of the bit line 170 is electrically connected to the transistors 140 that are arranged along X-direction through the respective bit line contacts 160, in which each of the bit line contacts 160 is electrically connected to the transistor 140 of a respective one of the memory cells MC. The memory array further includes a plurality of body contacts 130. Each of The body contact 130 is vertically below the bit line contacts 160. That is, one body contact 130 corresponds with more than one bit line contact 160 and thus more than one transistor 140. The capacitors 110 are adjacent to a first side of the word line 154, the bit line contacts 160 are adjacent to a second side of the word line, in which the second side is opposite to the first side. That is, the capacitors 110 and the body contacts 130 are at opposite side of the word line 154.

During the operation of the transistor 140, electrons and holes are generated. The electrons are withdrawn by the drain 144. However, the holes may be swept toward the first dielectric layer 104 and as a transient storage. When the transistor 140 is turned off, the transient storage caused by the accumulated holes may result in OFF-state leakage current, which in turn will deteriorate the device performance. As a result, to reduce the accumulated holes in the semiconductive layer 142, the body contact 130 is disposed below and in contact with the semiconductive layer 142 to introduce the accumulated holes out of the semiconductive layer 142. Therefore, the OFF-state leakage current may be reduced.

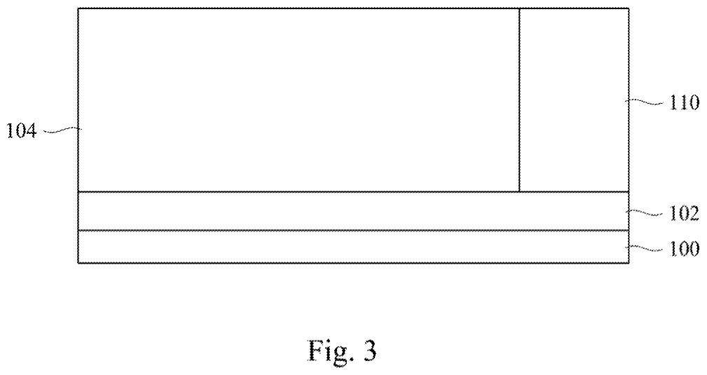

FIGS. 3-13 illustrate cross-section views of manufacturing method of the memory device in some embodiments of the present disclosure. Referring to FIG. 3, a conductive layer 102 and a first dielectric layer 104 are sequentially formed on a semiconductor substrate 100. In some embodiments, the semiconductor substrate 100 may be made of semiconductor material, such as polysilicon but the present disclosure is not limited thereto, the conductive layer 102 may be made of tungsten (W), Titanium nitride (TiN), tantalum nitride (TaN), but the present disclosure is not limited thereto, and the first dielectric layer 104 may be made of silicon oxide, silicon nitride, but the present disclosure is not limited thereto. Subsequently, the capacitor 110 is formed in the first dielectric layer 104. It is noted that FIG. 3 illustrates the capacitor 110 as a pillar for simplicity. In some embodiments, the capacitor 110 includes an insulating layer cladded by two electrodes.

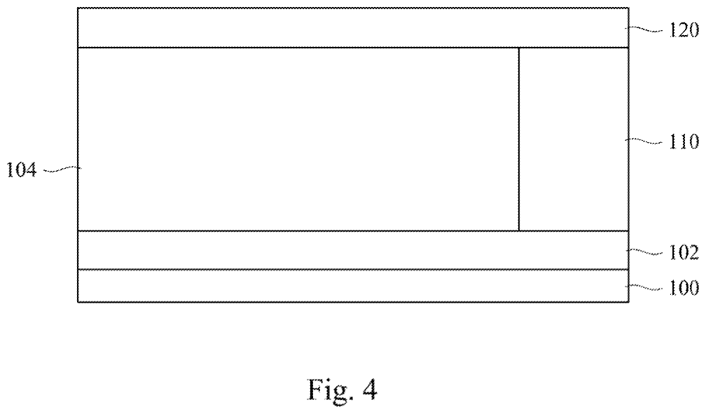

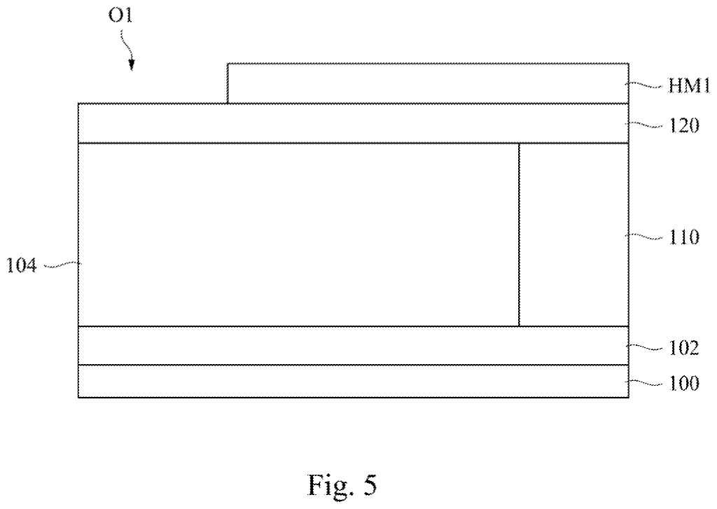

Referring to FIG. 4, a second dielectric layer 120 is formed over the first dielectric layer 104 and the capacitor 110. The second dielectric layer 120 may be made of silicon oxide, silicon nitride, but the present disclosure is not limited thereto. Referring to FIG. 5, a first hard mask layer HM1 is formed over the second dielectric layer 120. The first hard mask layer HM1 includes an opening O1 over the second dielectric layer 120 and exposing a portion of the second dielectric layer 120 not over the capacitor 110.

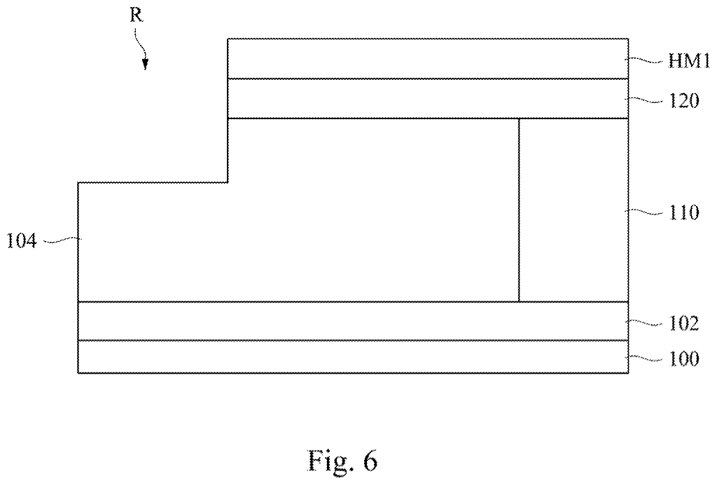

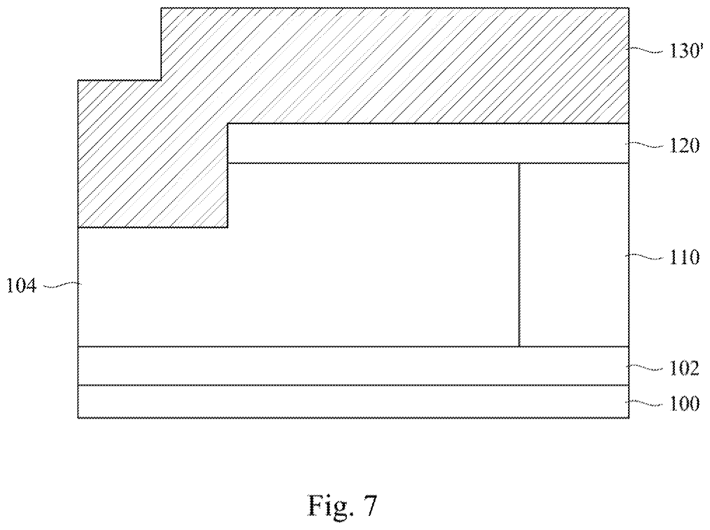

Referring to FIG. 6, a recess R is formed in the first dielectric layer 104 and the second dielectric layer 120 by etching the first dielectric layer 104 and the second dielectric layer 120 through the opening O1 of the first hard mask layer HM1. The recess R is spaced apart from the capacitor 110, so the recess R does not expose the capacitor 110. In some embodiments, different etchants may be used to etch the second dielectric layer 120 and the first dielectric layer 104. Referring to FIG. 7, the first hard mask layer HM1 is removed. Then, a body contact material layer 130′ is formed overfilling the recess R (see FIG. 6) and extending to top surface of the second dielectric layer 120. In some embodiments, the body contact material layer 130′ may be a semiconductive material or a conductive material. The semiconductive material may be p-type heavily doped polysilicon. The conductive material may be metal.

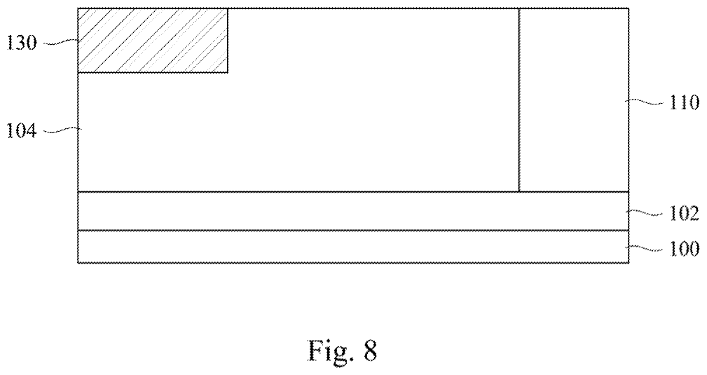

Referring to FIG. 8, a planarization process is performed to remove excess material of the body contact material layer 130′ until the first dielectric layer 104 is exposed. In some embodiments, during the planarization process, the second dielectric layer 120 is removed. On the other hand, the remaining portion of the body contact material layer 130′ is referred to as the body contact 130. As a result, the body contact 130 is formed in the first dielectric layer 104, and the body contact 130 is spaced apart from the capacitor 110. After the planarization process, the first dielectric layer 104 and the capacitor 110 are exposed.

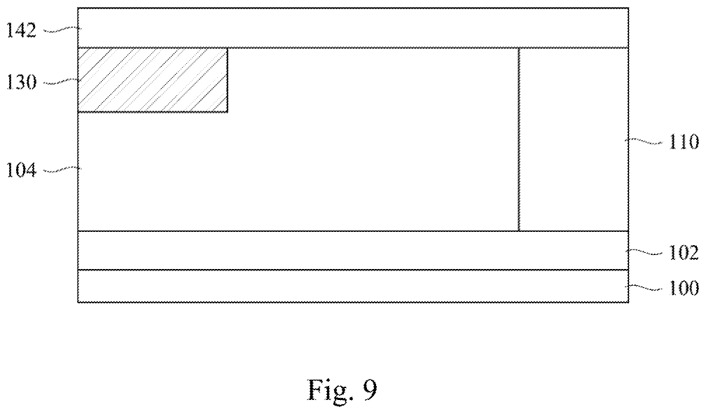

Referring to FIG. 9, a semiconductive layer 142 is formed over the first dielectric layer 104, and covers the capacitor 110 and the body contact 130. In some embodiments, the semiconductive layer 142 may be p-type moderately doped silicon. In the embodiments where the body contact 130 is made of semiconductive material, such as p-type heavily doped polysilicon, the doping concentration of the semiconductive layer 142 is lower than the doping concentration of the body contact 130.

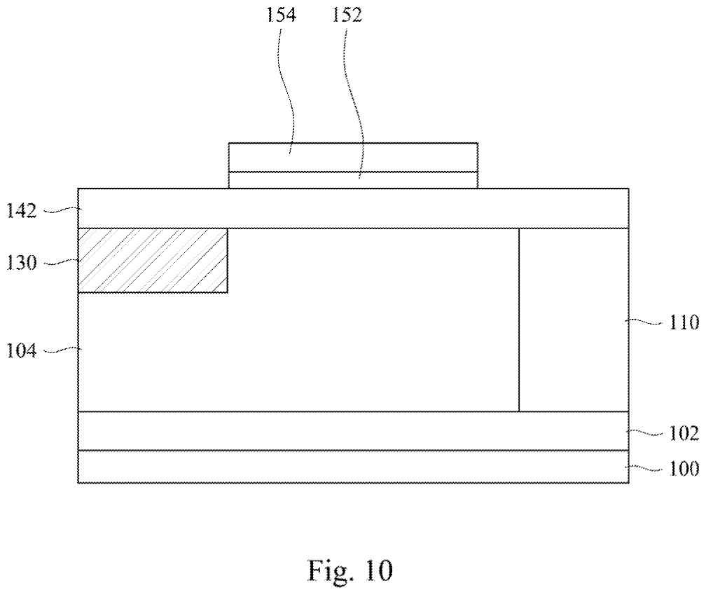

Referring to FIG. 10, a gate dielectric layer 152 and a word line 154 is formed over the semiconductive layer 142. Specifically, a dielectric material layer and a conductive material layer are sequentially formed on the semiconductive layer 142. Subsequently, the conductive material layer is patterned to form the word line 154, and then the dielectric material layer is etched by using the word line 154 as etch mask to form the gate dielectric layer 152. In some embodiments, the gate dielectric layer 152 is made of silicon oxide, silicon nitride, but the present disclosure is not limited thereto, and the word line 154 is made of metal, such as tungsten (W), copper (Cu), or molybdenum (Mo), but the present disclosure is not limited thereto.

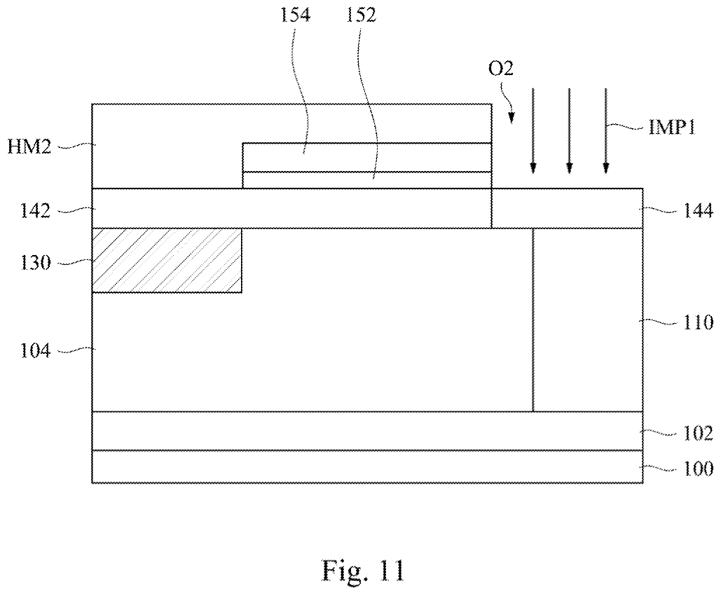

Referring to FIG. 11, the drain 144 is formed in the semiconductive layer 142 over the capacitor 110. Specifically, a second hard mask layer HM2 is formed over the word line 154 and the semiconductive layer 142 over the body contact 130. The second hard mask layer HM2 has an opening O2 overlapping the capacitor 110. Subsequently, a first implantation process IMP1 is performed to form the drain 144 through the opening O2 of the second hard mask layer. N-type dopants are implanted into the semiconductive layer 142 over the capacitor 110 during the first implantation process IMP1. The drain 144 may be made of n-type heavily doped silicon. The doping intensity of the first implantation process is controlled, so that the drain 144 is in contact with the capacitor 110.

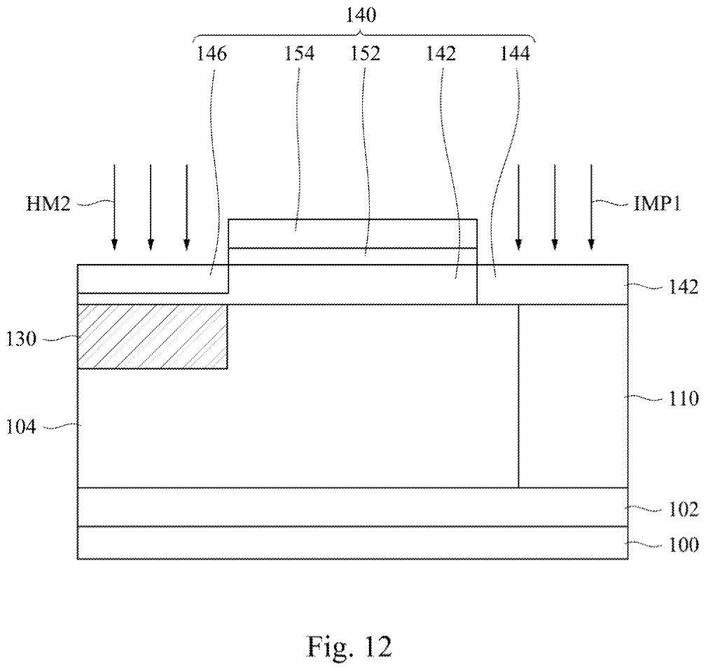

Referring to FIG. 12, the second hard mask layer HM2 is removed. Then, the source 146 is formed in the semiconductive layer 142 over the body contact 130. The source 146 vertically overlaps the body contact 130, while the source 146 is vertically spaced apart from the body contact 130. As such, a transistor 140 is formed over the semiconductive layer 142. Specifically, a second implantation process IMP2 is performed to form the source 146 in the semiconductive layer 142 and overlapping the body contact 130. N-type dopants are implanted into the semiconductive layer 142 over the capacitor 110 and the body contact 130 during the second implantation process IMP2. The source 146 may be made of n-type heavily doped silicon. The doping intensity of the second implantation process is controlled, so that the bottom of the source 146 is spaced apart from the body contact 130. That is, the doping intensity of the first implantation process IMP1 is stronger than the doping intensity of the second implantation process IMP2, so that the bottom of the drain 144 is lower than the bottom of the source 146. Since the bottom of the drain 144 is lower than the bottom of the source 146, the n-type dopants implanted into the drain 144 during the second implantation process IMP2 does not affect the range of the drain 144.

In some embodiments, the capacitor 110 is formed before the formation of the source 146. Therefore, the thermal process of the capacitor 110 will not affect the range of the source 146. For example, the dopants of the source 146 will not diffuse during the thermal process for forming the capacitor 110, so the source 146 will not be in contact with the body contact 130. In the embodiments where the body contact 130 is made of semiconductive material, such as p-type heavily doped polysilicon, the semiconductive layer 142 extending between the body contact 130 and the source 146 may avoid the junction between the p-type heavily doped region (i.e. body contact 130) and the n-type heavily doped region (i.e. source 146). Therefore, the OFF-state leakage current due to the junction between the p-type heavily doped region (i.e. body contact 130) and the n-type heavily doped region (i.e. source 146) may also be reduced.

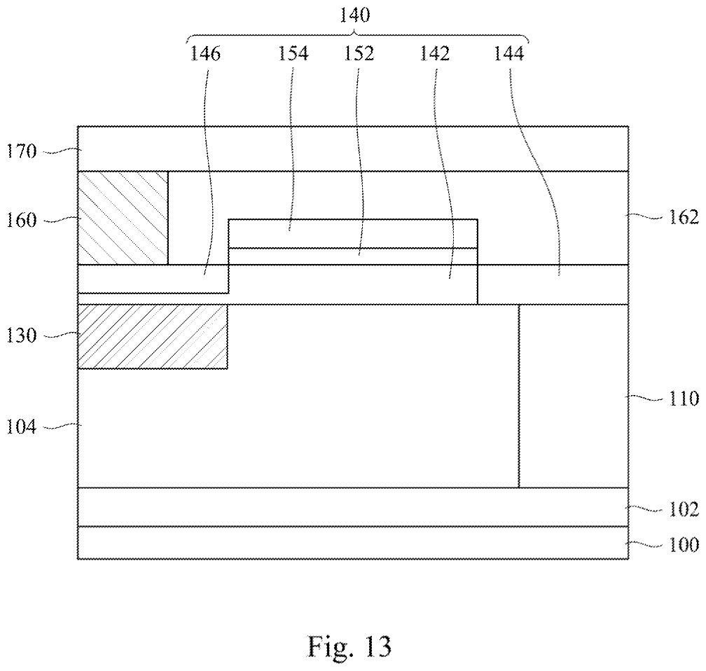

Referring to FIG. 13, the bit line contact 160 is formed in contact with the source 146. Specifically, a dielectric layer 162 is firstly formed over the semiconductive layer 142 and covering the word line 154. Subsequently, the bit line contact 160 is formed in the dielectric layer 162 and on the source 146. The bit line contact 160 vertically overlaps the body contact 130 after forming the bit line contact 160. Subsequently, the bit line 170 is formed on the bit line contact 160 and the dielectric layer 162. In some embodiments, the bit line contact 160 is made of conductive material, such as tungsten (W), Titanium nitride (TiN), tantalum nitride (TaN), doped semiconductor material (e.g., p-doped or n-doped silicon), and/or other CMOS contact metals. The dielectric layer 162 may be made of silicon oxide, silicon nitride, but the present disclosure is not limited thereto. The bit line 170 is made of metal, such as tungsten (W), copper (Cu), or molybdenum (Mo), but the present disclosure is not limited thereto.

As mentioned above, the body contact of the memory device may be used to introduce the accumulated holes out of the body of the transistor to reduce the OFF-state leakage current. The body contact is in contact with the body of the transistor, and is spaced apart from the source of the transistor. Therefore, in some embodiments where the body contact is made of p-type heavily doped region and the source is made of n-type heavily doped region, the junction between the p-type heavily doped region and the n-type heavily doped region is avoided. Therefore, the OFF-state leakage current due to the junction between the p-type heavily doped region and the n-type heavily doped region may also be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a substrate;
a capacitor over the substrate;
a transistor over the capacitor, wherein the transistor comprises:
a channel region;
a gate over the channel region; and
a source and a drain on opposite sides of the channel region, wherein the drain is over the capacitor;
a word line over and electrically connected to the gate of the transistor;
a bit line contact over and electrically connected to the source of the transistor; and
a body contact below the source of the transistor.

2. The memory device of claim 1, wherein a bottom of the drain is lower than a bottom of the source.

3. The memory device of claim 1, wherein a bottom of the source is vertically spaced apart from the body contact.

4. The memory device of claim 1, wherein the bit line contact vertically overlaps the body contact.

5. The memory device of claim 1, wherein the drain is in contact with the capacitor.

6. The memory device of claim 1, further comprising
a bit line over and in contact with the bit line contact.

7. A memory device, comprising:
a plurality of memory cells, wherein each of the memory cells comprises:
a transistor; and
a capacitor electrically connected to the transistor;
a word line electrically connected to the transistor of each of the memory cells;
a plurality of bit line contacts, wherein each of the bit line contacts is electrically connected to the transistor of a respective one of the memory cells; and
a body contact vertically below the bit line contacts.

8. The memory device of claim 7, wherein the capacitor is in contact with a bottom of a drain of the transistor.

9. The memory device of claim 7, wherein the transistor is at a higher level than the capacitor.

10. The memory device of claim 7, wherein the bit line contacts and the body contact are at opposite sides of a source of the transistor.

11. The memory device of claim 7, wherein the body contact and the capacitor are at a lower level than the transistor.

12. A manufacturing method of a memory device, comprising:
forming a capacitor in a first dielectric layer;
forming a body contact in the first dielectric layer, wherein the body contact is spaced apart from the capacitor;
forming an semiconductive layer over the first dielectric layer and covering the capacitor and the body contact;
forming a transistor over the semiconductive layer; and
forming a bit line contact in contact with a source of the transistor.

13. The manufacturing method of claim 12, wherein forming the body contact comprises:
forming a second dielectric layer over the first dielectric layer and the capacitor;
forming a hard mask layer having an opening over the second dielectric layer;
etching the first dielectric layer and the second dielectric layer through the opening of the hard mask layer to form a recess in the first dielectric layer and the second dielectric layer;
removing the hard mask layer;
forming a body contact material layer overfilling the recess; and
performing a planarization process to the body contact material layer until the first dielectric layer is exposed.

14. The manufacturing method of claim 12, wherein forming the transistor comprises:
forming a hard mask layer over the semiconductive layer, wherein the hard mask layer has an opening overlapping the capacitor;
performing a first implantation process to form a drain of the transistor in the semiconductive layer through the opening of the hard mask layer as mask; and
removing the hard mask layer.

15. The manufacturing method of claim 14, wherein forming the transistor further comprises:
performing a second implantation process to form the source of the transistor in the semiconductive layer and overlapping the body contact.

16. The manufacturing method of claim 15, wherein a doping intensity of the first implantation process is stronger than a doping intensity of the second implantation process.

17. The manufacturing method of claim 12, wherein a source of the transistor vertically overlaps the body contact, while the source of the transistor is vertically spaced apart from the body contact.

18. The manufacturing method of claim 12, wherein a drain of the transistor is in contact with the capacitor.

19. The manufacturing method of claim 12, wherein a bottom of a drain of the transistor is lower than a bottom of a source of the transistor.

20. The manufacturing method of claim 12, further comprising:
forming a bit line in contact with the bit line contact.
